(19) United States
(12) Patent Application Publication
(10) Pub. No.: US 2026/0290461 A1
(43) Pub. Date: Sep. 24, 2026

(54) NONVOLATILE MEMORY WITH MULTIPLE PROGRAM SCHEMES

(71) Applicant: Micron Technology, Inc., Boise, ID (US)

(72) Inventors: Yu-Chung Lien, San Jose, CA (US); Zhenming Zhou, San Jose, CA (US)

(21) Appl. No.: 19/084,296

(22) Filed: Mar. 19, 2025

(51) Int. Cl. G11C 16/10; G11C 16/08; G11C 16/24; G11C 16/34

(52) U.S. Cl. CPC G11C 16/102; G11C 16/08; G11C 16/24; G11C 16/3459

(57) ABSTRACT

A system and method for programming data to a memory device are disclosed. The system and method receive a command associated with programming data to a portion of a memory device. The system and method determine an individual programming scheme from a plurality of programming schemes available on the memory device based on the received command and program data to the portion of the memory device using the determined individual programming scheme.

### TECHNICAL FIELD

This disclosure relates generally to memory sub-systems and, more specifically, to providing adaptive programming schemes for memory components such as memory dies.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various examples of the disclosure. The drawings, however, should not be taken to limit the disclosure to the specific examples, but are for explanation and understanding only.

FIG. 1 is a block diagram illustrating an example computing system that includes a memory sub-system, in accordance with some examples.

FIG. 2 illustrates an incremental step program pulse (ISPP) and all-level programming (ALP) program scheme, in accordance with some examples.

FIG. 3 illustrates an analog selective slow program convergence (aSSPC) program scheme, in accordance with some examples.

FIG. 4 illustrates a diagram of operations performed using the media operations manager, in accordance with some examples.

FIG. 5 is a block diagram of an example computer system, in accordance with some examples.

### DETAILED DESCRIPTION

The present disclosure configures a memory device to implement multiple programming schemes in the same memory device to accommodate various performance specifications or requirements. Specifically, the memory device includes both ISPP scheme and at least one advanced programming scheme, such as an ALP scheme and aSSPC programming scheme. The programming schemes can be selected based on prefix commands (received from a host system), where different memory sub-systems (e.g., corresponding to different products) using the same memory device can use different schemes based on their performance needs. For example, memory sub-systems with the disclosed memory device implemented in products with lower performance needs (e.g., slower program times) may program the memory device using the ISPP scheme, while memory sub-systems with the same disclosed memory device in products with more aggressive performance targets can program the same memory device using ALP or aSSPC programming schemes that provide faster programming speeds. This approach maintains ISPP as a backup programming scheme to mitigate risks while enabling advanced schemes for higher performance needs. The programming schemes can be implemented across different memory types including multi-level cell (MLC), tri-level cell (TLC), quad-level cell (QLC), single-level cell (SLC), and/or dual SLC with pillar float; different programming orders (drain-to-source (D2S) or source-to-drain (S2D)), and/or different block types (normal blocks, partial good blocks, or blocks by deck). This improves the overall efficiency of the memory device by allowing flexible selection of programming schemes based on product needs while maintaining reliability through backup schemes.

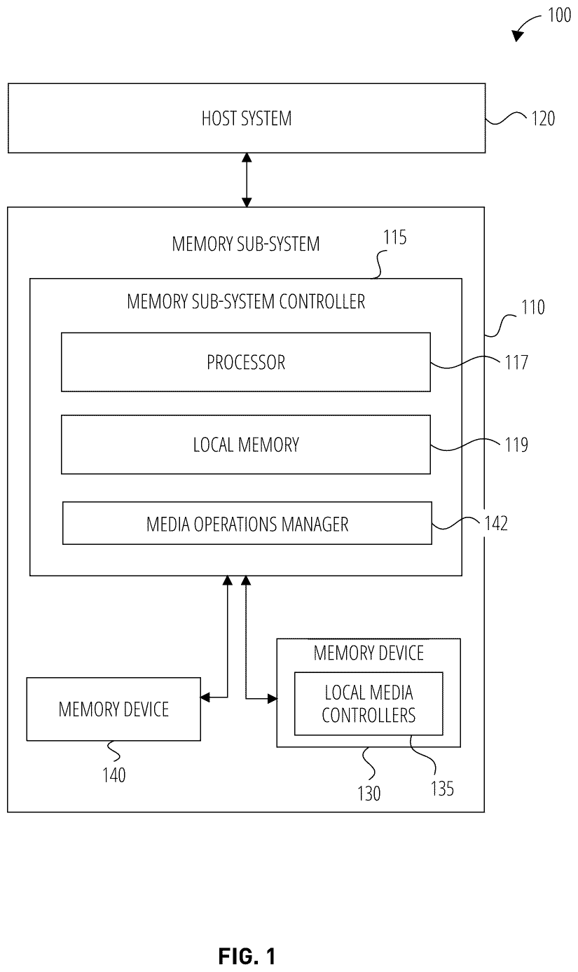

A memory sub-system can be a storage device, a memory module (memory component), or a hybrid of a storage device and memory module. Examples of storage devices and memory modules are described below in conjunction with FIG. 1. In general, a host system can utilize a memory sub-system that includes one or more memory components, such as memory devices (e.g., memory dies or planes across multiple memory dies) that store data. The host system can send access requests (e.g., write command, read command) to the memory sub-system, such as to store data at the memory sub-system and to read data from the memory sub-system. The data (or set of data) specified by the host is hereinafter referred to as “host data,” “application data,” or “user data.”

The memory sub-system can initiate media management operations, such as a write operation, on host data that is stored on a memory device. In some examples, firmware of the memory sub-system may re-write previously written host data from a location on a memory device to a new location as part of garbage collection management operations. The data that is re-written, for example as initiated by the firmware, is hereinafter referred to as “garbage collection data.” “User data” can include host data and garbage collection data. “System data” hereinafter refers to data that is created and/or maintained by the memory sub-system for performing operations in response to host requests and for media management. Examples of system data include, and are not limited to, system tables (e.g., logical-to-physical address mapping table), data from logging, scratch pad data, etc.

Many different media management operations can be performed on the memory device. For example, the media management operations can include different scan rates, different scan frequencies, different wear leveling, different read disturb management, different near miss error correction code (ECC), and/or different dynamic data refresh. Wear leveling ensures that all blocks in a memory component approach their defined erase-cycle budget at the same time, rather than some blocks approaching it earlier. Read disturb management counts all of the read operations to the memory component and if a certain threshold is reached, the surrounding regions are refreshed. Near-miss ECC refreshes all data read by the application that exceeds a configured threshold of errors. Dynamic data-refresh scan reads all data and identifies the error status of all blocks as a background operation. If a certain threshold of errors per block or ECC unit is exceeded in this scan-read, a refresh operation is triggered.

A memory device can be a non-volatile memory device. A non-volatile memory device is a package of one or more dice (or dies). Each die can be comprised of one or more planes. For some types of non-volatile memory devices (e.g., NAND devices), each plane is comprised of a set of physical blocks. For some memory devices, blocks are the smallest areas that can be erased. Such blocks can be referred to or addressed as logical units (LUN). Each block is comprised of a set of pages. Each page is comprised of a set of memory cells, which store bits of data. The memory devices can be raw memory devices (e.g., NAND), which are managed externally, for example, by an external controller. The memory devices can be managed memory devices (e.g., managed NAND), which are raw memory device combined with a local embedded controller for memory management within the same memory device package.

In conventional systems using ISPP (Incremental Step Pulse Programming), memory cells (e.g., in MLC, TLC, and/or QLC memory devices) are programmed level-by-level. This level-by-level approach can require a significant number of programming pulses to complete the programming operation. The sequential nature of conventional ISPP programming creates several inefficiencies, such as the increased power consumption and programming latency. This sequential programming approach can require programming and verifying each level separately, which results in longer programming times and higher power consumption. The conventional ISPP scheme faces difficulty meeting performance targets while maintaining reliability as memory array capacity scales up.

The conventional approach can result in significant performance degradation in programming times. This performance impact makes conventional programming schemes less useful. The level-by-level programming sequence also requires maintaining consistent voltage thresholds across multiple programming phases, increasing system complexity and the likelihood of programming errors if precise voltage control is not maintained throughout the entire sequence. The lack of flexibility in choosing advanced programming schemes makes it difficult to accommodate various performance needs across different products using the same memory device or memory sub-system, particularly as the performance gap between different product needs tends to enlarge.

The present disclosure addresses technical challenges by implementing multiple programming schemes in the same memory device to accommodate different performance needs. The memory device includes both conventional ISPP and one or more advanced programming schemes, like ALP and aSSPC. Different programming schemes can be selected via prefix commands based on product requirements. Namely, lower performance products can use conventional ISPP while higher performance products utilize advanced schemes. The ALP scheme reduces programming time and energy per bit compared to ISPP by simultaneously programming multiple levels through controlled bit line biasing and channel boosting. The aSSPC scheme provides even greater improvements with faster programming through finer granularity control of bit line biases during programming. This flexible approach maintains ISPP as a backup programming scheme while enabling advanced schemes for products with more aggressive performance targets. The programming schemes can be implemented across different memory types (MLC, TLC, QLC, SLC, dual SLC), programming orders (D2S or S2D), and/or block types (normal, partial good, or block by deck). This improves overall efficiency by allowing selection of optimal programming schemes based on specific product needs while maintaining reliability through backup schemes.

In addition, by implementing multiple programming schemes in the same memory device, manufacturers can avoid having to produce separate memory devices for different performance needs. This unified approach allows a single memory device design to serve multiple product needs through software-selectable programming schemes, reducing manufacturing complexity and costs while maintaining flexibility to meet diverse performance targets.

In some examples, a memory sub-system includes a memory device with multiple programming schemes that can be selected based on commands received from a host system. The memory device implements both ISPP and one or more advanced programming schemes to accommodate different performance requirements across products. The ISPP scheme uses smaller voltage step sizes for more accurate voltage threshold placement. The ISPP scheme can use approximately 17 programming loops to complete programming operations.

In some cases, the one or more advanced programming schemes include an ALP scheme that simultaneously programs multiple levels by toggling bit line biases at different Vpass thresholds and ramping the staircase Vpass for unselected WLs. In some implementations, the one or more advanced programming schemes include an aSSPC scheme that provides finer granularity control of bit line biases during programming. The programming schemes used by the memory sub-system to program data to the memory device can be selected through prefix commands, enabling the memory device to serve multiple product needs through software-selectable schemes rather than requiring separate memory devices for different performance targets. For example, the memory sub-system includes a processing device, operatively coupled to the memory device, programmed to receive a command associated with programming data to a portion of the memory device and determine an individual programming scheme from the plurality of programming schemes available on the memory device based on the received command. The processing device can program data to the portion of the memory device using the determined individual programming scheme.

For instance, when initially operating with an ALP scheme for high performance needs, the processing device may subsequently receive a new command to switch to the ISPP scheme. This can happen when performance needs are reduced (e.g., when a time needed to program data to individual cells or portions is reduced). This flexibility allows the same memory device to dynamically adjust its programming scheme based on changing performance needs, where products (in which the memory sub-system is implemented) with lower performance needs can use ISPP while products requiring more aggressive performance targets can utilize advanced schemes like ALP or aSSPC. For example, the processing device can monitor programming performance metrics and automatically determine when to switch programming schemes. Namely, if programming time needs become less stringent, the processing device can switch from ALP or aSSPC to the ISPP scheme, which serves as a reliable backup option. Additionally, the same processing device can dynamically adjust the programming scheme used by the memory sub-system over its lifetime as performance requirements evolve, such as using advanced schemes like ALP or aSSPC during high-performance periods, while falling back to ISPP during periods of reduced performance needs. This flexibility allows the memory device to optimize its operation based on real-time performance measurements and thresholds, rather than being locked into a single programming scheme.

The memory device can include different types of memory cells, including (SLC, MLC, TLC, or QLC configurations. The programming schemes can be implemented across different memory architectures including 3D NAND, ReRAM, and PCM. In other examples, the system supports programming in either D2S or S2D directions and can be used with different block types including normal blocks, partial good blocks, or blocks by deck.

In some implementations, the system can apply different programming schemes to different sub-blocks based on their specific performance requirements. This allows optimizing performance across different portions of the memory device while maintaining ISPP as a backup programming scheme.

Though various examples are described herein as being implemented with respect to a memory sub-system (e.g., a controller of the memory sub-system), some or all of the portions of an embodiment can be implemented with respect to a host system, such as a software application or an operating system of the host system.

FIG. 1 illustrates an example computing system 100 that includes a memory sub-system 110, in accordance with some examples. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, a secure digital (SD) card, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and various types of non-volatile dual in-line memory module (NVDIMM).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some examples, the host system 120 is coupled to different types of memory sub-systems 110. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, and the like.

The host system 120 can include a processor chipset and a software stack executed by the processor chipset. The processor chipset can include one or more cores, one or more caches, a memory controller (e.g., NVDIMM controller), and a storage protocol controller (e.g., a peripheral component interconnect express (PCIe) controller, serial advanced technology attachment (SATA) controller). The host system 120 uses the memory sub-system 110, for example, to write data to the memory sub-system 110 and read data from the memory sub-system 110.

The host system 120 can include or be coupled to the memory sub-system 110 so that the host system 120 can read data from or write data to the memory sub-system 110. The host system 120 can be coupled to the memory sub-system 110 via a physical host interface. Examples of a physical host interface include, but are not limited to, a serial advanced technology attachment (SATA) interface, a peripheral component interconnect express (PCIe) interface, a compute express link (CXL) interface, a universal serial bus (USB) interface, a Fibre Channel interface, a Serial Attached SCSI (SAS) interface, etc. The physical host interface can be used to transmit data between the host system 120 and the memory sub-system 110. The host system 120 can further utilize an NVM Express (NVMe) interface to access the memory devices 130, 140 when the memory sub-system 110 is coupled with the host system 120 by the PCIe or CXL interface. The physical host interface can provide an interface for passing control, address, data, and other signals between the memory sub-system 110 and the host system 120.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a NAND flash memory and write-in-place memory, such as a 3D cross-point memory device, which is a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional (2D) NAND and 3D NAND.

Each of the memory devices 130, 140 can include one or more arrays of memory cells. One type of memory cell, for example, single level cells (SLCs), can store one bit per cell. Other types of memory cells such as, dual SLC with pillar float, multi-level cells (MLCs), tri-level cells (TLCs), quad-level cells (QLCs), and/or penta-level cells (PLCs), can store multiple bits per cell. In some examples, each of the memory devices 130, 140 can include one or more arrays of memory cells such as SLCs, MLCs, TLCs, QLCs, or any combination of such. In some examples, a particular memory device can include an SLC portion, and an MLC portion, a TLC portion, or a QLC portion of memory cells. The memory cells of the memory devices 130, 140 can be grouped as pages that can refer to a logical unit of the memory device used to store data. With some types of memory (e.g., NAND), pages can be grouped to form blocks or BSs. As used herein, a block comprising SLCs can be referred to as a SLC block, a block including MLCs can be referred to as a MLC block, a block comprising TLCs can be referred to as a TLC block, and a block including QLCs can be referred to as a QLC block.

Although non-volatile memory components such as NAND-type flash memory (e.g., 2D NAND, 3D NAND) and 3D cross-point array of non-volatile memory cells are described, the memory device 130 can be based on any other type of non-volatile memory, such as read-only memory (ROM), phase change memory (PCM), self-selecting memory, other chalcogenide-based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (ReRAM), oxide-based RRAM (OxRAM), negative-or (NOR) flash memory, and electrically erasable programmable read-only memory (EEPROM).

A memory sub-system controller 115 (or controller 115 for simplicity) can communicate with the memory devices 130, 140 to perform operations such as reading data, writing data, or erasing data (e.g., performing garbage collection (GC) operations) at the memory devices 130, 140 and other such operations. The memory sub-system controller 115 can include hardware such as one or more integrated circuits and/or discrete components, a buffer memory, or a combination thereof. The hardware can include digital circuitry with dedicated (e.g., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor (processing device) 117 configured to (or programmed to) execute instructions stored in local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some examples, the local memory 119 can include memory registers storing memory pointers, fetched data, and so forth. The local memory 119 can also include ROM for storing micro-code. While the example memory sub-system 110 in FIG. 1 has been illustrated as including the memory sub-system controller 115, in another example, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device 130 and/or the memory device 140. The memory sub-system controller 115 can be responsible for other operations such as wear leveling operations, GC operations, error detection and ECC operations, encryption operations, caching operations, and address translations between a logical address (e.g., logical block address (LBA), namespace) and a physical memory address (e.g., physical block address in a physical address space of the memory device 130 or memory device 140) that are associated with the memory devices 130, 140. The memory sub-system controller 115 can further include host interface circuitry to communicate with the host system 120 via the physical host interface. The host interface circuitry can convert the commands received from the host system 120 into command instructions to access the memory device 130 and/or the memory device 140 as well as convert responses associated with the memory device 130 and/or the memory device 140 into information for the host system 120.

The memory sub-system 110 can also include additional circuitry or components that are not illustrated. In some examples, the memory sub-system 110 can include a cache or buffer (e.g., DRAM) and address circuitry (e.g., a row decoder and a column decoder) that can receive an address from the memory sub-system controller 115 and decode the address to access the memory devices 130, 140.

In some examples, the memory device 130 includes local media controllers 135 that operate in conjunction with memory sub-system controller 115 to execute operations on one or more memory cells of the memory device 130. An external controller (e.g., memory sub-system controller 115) can externally manage the memory device 130 (e.g., perform media management operations on the memory device 130). In some examples, a memory device 130 is a managed memory device, which is a raw memory device combined with a local controller (e.g., local media controller 135) for media management within the same memory device package. An example of a managed memory device is a managed NAND (MNAND) device. Any operation discussed as being performed by the memory sub-system controller 115 can be similarly performed by the local media controllers 135 and vice versa.

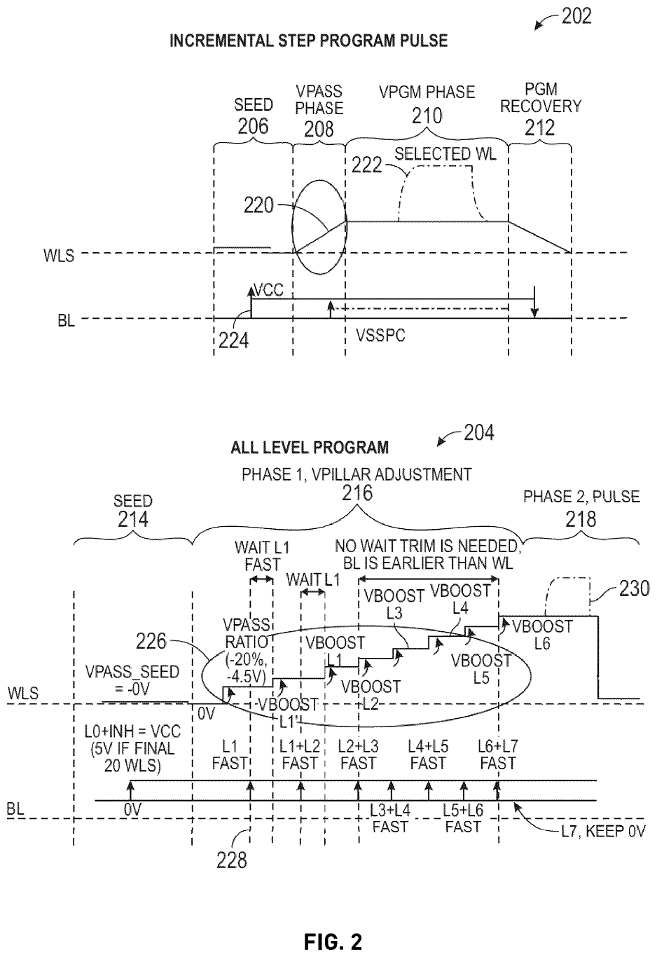

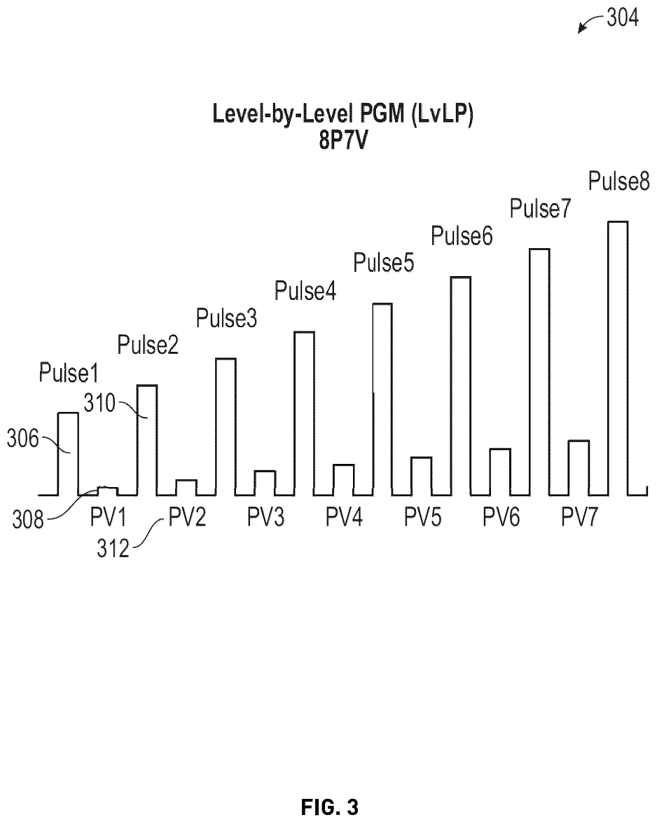

The memory device 130 can be configured to program data according to any selected programming scheme from multiple programming schemes. Namely, the memory device 130 can implement multiple programming schemes, such as ISPP, ALP, and/or aSSPC. The local media controllers 135 and/or media operations manager 142 can select the individual programming scheme and program data received from the host system 120 into the memory device 130 using the selected programming scheme. The specific operations for programming data according to the ISPP, ALP, and aSSPC programming schemes are discussed below in connection with FIG. 2 and FIG. 3.

The memory sub-system 110 can include a media operations manager 142. The media operations manager 142 receives prefix commands associated with programming data to portions of the memory device 130 and determines which programming scheme to use based on the prefix commands. For example, the media operations manager 142 can select between ISPP and one or more advanced programming schemes, such as ALP or aSSPC depending on performance needs.

When implementing the ALP scheme, the media operations manager 142 controls bit line biasing to simultaneously program multiple levels, reducing programming time compared to ISPP by using only 6 programming loops instead of 17. The media operations manager 142 achieves this by applying different bit line biases to create different boosting potentials for each target level. For aSSPC operations, the media operations manager 142 checks program speed (VgVt) from previous verify operations and dynamically adjusts bit line bias voltages to provide finer granularity control over programming speed. This enables completing one level per program pulse and improves programming time.

The media operations manager 142 can monitor programming performance metrics in real-time and automatically switch between schemes based on changing requirements. For instance, the media operations manager 142 may switch from ALP to ISPP when performance needs become less stringent. The media operations manager 142 may switch from ISPP to ALP when performance needs become more aggressive (e.g., less time is allowed for programming data).

The media operations manager 142 can monitor several performance metrics to determine when to switch between programming schemes. The media operations manager 142 can measure the number of programming loops required and can track the total programming time per word line or block. The media operations manager 142 can compare actual programming time against target thresholds for different performance requirements. In some cases, the media operations manager 142 monitors energy per bit (EPB) consumption. The media operations manager 142 can determine that a higher EPB indicates a need to switch to a more efficient scheme. In some cases, the media operations manager 142 tracks product-specific performance targets (e.g., TLC tProg requirements) and compares current programming speed against required thresholds. When performance needs become less stringent (higher allowable programming time), the media operations manager 142 switches to ISPP. When aggressive performance is needed (lower required programming time), the media operations manager 142 switches to ALP or aSSPC. In some examples, the media operations manager 142 monitors threshold voltage placement accuracy. If tighter voltage distributions are needed, the media operations manager 142 may switch to ISPP for more precise control and if wider distributions are acceptable, the media operations manager 142 can use faster schemes like ALP.

The media operations manager 142 compares these metrics against predefined thresholds to automatically determine when to switch schemes. For example, if programming time exceeds the target threshold for a particular product requirement, it may switch from ISPP to ALP to achieve faster programming. Conversely, if performance requirements become less stringent and programming accuracy becomes more critical, the media operations manager 142 can switch from advanced schemes back to ISPP.

For multi-block operations, the media operations manager 142 can determine and apply different programming schemes to different sub-blocks based on their specific performance requirements. This allows improving performance across different portions while maintaining ISPP as a backup. Namely, the media operations manager 142 can determine and apply different programming schemes to different sub-blocks of the same memory device 130 based on their specific performance requirements. For example, when receiving commands to program data, the media operations manager 142 can determine a first programming scheme (e.g., ISPP) for one sub-block that has lower performance requirements, while selecting an advanced scheme (e.g., ALP or aSSPC) for another sub-block requiring faster programming speeds. This allows the media operations manager 142 to tailor performance across different portions of the memory device 130 while maintaining ISPP as a reliable backup option. The media operations manager 142 can program data to the first sub-block using the conventional ISPP scheme while simultaneously programming data to the second sub-block using an advanced scheme like ALP that provides a first amount of faster programming or aSSPC that offers a second amount of faster programming. This flexibility enables the media operations manager 142 to accommodate varying performance requirements across different portions of the same memory device.

Additionally, the media operations manager 142 can monitor programming performance metrics for each sub-block and dynamically adjust the programming schemes based on changing requirements. This allows for optimal programming efficiency across the memory device by using faster schemes where needed while maintaining reliability through ISPP in other portions.

The media operations manager 142 can support programming across different memory types including MLC, TLC, QLC and SLC configurations. The media operations manager 142 can implement the schemes in either drain-to-source or source-to-drain programming directions.

When using ISPP, the media operations manager 142 applies smaller voltage step sizes for more precise threshold voltage placement. This provides reliable programming when aggressive performance is not required. The media operations manager 142 maintains ISPP as a backup scheme while enabling advanced schemes for products with more aggressive performance targets. This provides flexibility while ensuring reliability.

The media operations manager 142 can dynamically adjust programming schemes over the memory sub-system 110 lifetime as performance requirements evolve. This allows changing operations based on real-time measurements rather than being locked into a single scheme. The media operations manager 142 enables a single memory device design to serve multiple product needs through software-selectable programming schemes, obviating the need for separate memory devices for different performance targets.

Any discussion with respect to the memory device 130 can similarly be applied to the memory device 140. Any function pertaining to the local media controllers 135 can, in some cases, be performed by the device) memory sub-system controller 115.

FIG. 2 illustrates a ISPP diagram 202 and an ALP diagram 204, in accordance with some examples. Namely, FIG. 2, illustrates two distinct programming approaches, schemes, or types. These include the ISPP programming scheme shown in the ISPP diagram 202 and the ALP programming scheme shown in the ALP diagram 204.

The ISPP diagram 202 begins with an ISPP seed phase 206 where initial conditions are established. The word lines (WLs) and bit lines (BLs) are set to their initial voltages during this phase. The ISPP Vpass phase 208 follows, where unselected WLs are raised to their pass voltage levels. Unlike ALP, this is a direct ramping without the staircase pattern.

During the ISPP voltage program phase 210, the selected WL receives programming pulses (e.g., selected WL program pulse 230) with a smaller voltage step size. This smaller step size allows for more precise threshold voltage placement during the fine programming phase. The ISPP scheme includes an ISPP program recovery phase 212 after each programming pulse, where voltages are returned to their initial states before the next programming cycle begins.

The ISPP approach can require more programming loops compared to ALP, but provides more precise control over the final threshold voltage placement. Between programming loops in both schemes, program verify operations can be performed by the media operations manager 142 to ensure proper programming of the cells. These verify operations help maintain programming accuracy throughout both the coarse and fine programming phases.

A selected WL program pulse 222 in the ISPP and ALP schemes receives different voltage patterns. Namely, a staircase pattern (discussed below) is applied by the media operations manager 142 for ALP and the incremental step increases is applied by the media operations manager 142 for ISPP. Unselected WLs 220 maintain pass voltages during programming. Bit line 224 behavior differs between the two programming schemes. In ALP, the bit lines are controlled to achieve different boosting potentials simultaneously, while in ISPP, the bit lines 224 maintain more consistent voltages during programming.

For example, the ALP programming sequence begins with an ALP seed phase 214. The ALP seed phase 214 is where the WLs are initialized at a low voltage level (Vpass_seed≈0V). During this phase, the BLs are set to either VCC for inhibited cells or 0V for cells to be programmed. Following the seed phase, the ALP scheme enters an ALP first Vpass phase 216, which implements a distinctive staircase waveform pattern. During this phase, the selected WL voltage increases in steps while different BLs are activated at specific timing intervals. This staircase approach allows for simultaneous programming of multiple levels by controlling the boosting potentials for each target level.

An ALP second Vpass phase 218 continues the staircase pattern, with BL biases being adjusted to achieve different boosting potentials (Vpillar) for different target levels. This phase is important for establishing the proper channel potentials that determine the final threshold voltages of the cells. During the ALP voltage pass phases, the WL voltage follows a controlled staircase pattern where it remains at specific levels while waiting for BL bias stabilization. This allows for precise control of the boosting conditions for each target level. The BL voltages during ALP are dynamically controlled, with different BLs being turned on at different times corresponding to their target programming levels. This creates different boosting potentials that determine how much each cell will be programmed.

For example, an individual level bit line boosting 228 represents the individual level BL boosting that occurs during the ALP coarse programming operation. The individual level bit line boosting 228 shows how different BLs are controlled to achieve different boosting potentials for different target levels simultaneously. During the voltage pass phase, the BLs are turned on at different timing intervals, creating distinct channel potentials that determine how much each cell will be programmed. This individual level bit line boosting 228 is a key feature that enables ALP to program multiple cells to different threshold voltages in parallel, as opposed to the sequential programming approach used in ISPP. The BL boosting control shown by individual level bit line boosting 228 works in conjunction with the staircase voltage 226 (e.g., staircase waveform) applied to the WLs to achieve the simultaneous programming of multiple levels during the coarse programming phase.

FIG. 3 illustrates an aSSPC programming scheme 304, in accordance with some examples. Specifically, FIG. 3 illustrates a level-by-level programming (LvLP) scheme implemented using the aSSPC approach. The aSSPC programming scheme 304 represents the overall programming sequence consisting of eight programming pulses (Pulse1 through Pulse8) and seven program verify operations (PV1 through PV7).

In some examples, a first program pulse 306 is applied to begin programming the memory cells of the memory device 130. After this initial pulse, a program verify operation is performed at voltage level PV1, indicated by the first program verify voltage 308. This verify operation checks if the cells have reached their target threshold voltages.

A second programming pulse 310 is then applied with an incrementally higher voltage to continue programming cells that have not reached their target levels. Another verify operation is performed at voltage level PV2, represented by a second program verify voltage 312. This pattern continues through subsequent pulses and verify operations. Each programming pulse (Pulse3 through Pulse8) increases in amplitude to provide stronger programming for cells that require additional voltage to reach their target levels. The corresponding verify voltages (PV3 through PV7) check the programming status after each pulse.

The aSSPC programming scheme 304 improves programming efficiency by requiring only eight programming pulses and seven verify operations (8P7V) compared to ISPP which needs approximately 17 programming loops. This represents an improvement in programming time. The aSSPC programming scheme 304 checks the VgVt (program speed) of cells from the previous verify operation and adjusts bit line biases during the current program pulse accordingly. This allows for finer granularity control over programming speeds.

For example, during the first pulse (VPGM=13.0V), all cells begin programming. After verifying L1 cells, the scheme measures VgVt for L2 cells. The second pulse (VPGM=14.3V) then applies customized bit line biases based on the measured speeds; faster cells receive higher bit line voltages to slow their programming, while slower cells maintain lower voltages. This pattern continues through all levels, with each pulse optimized based on the previous verify operation's measurements. Specifically, the initial programming pulse can have a program voltage (Vpgm) of 13.0V. The media operations manager 142 can apply a first programming pulse to all cells and perform a verify operation to check VgVt (programming speed) of each cell. For cells targeting L1, if VgVt indicates fast programming, the media operations manager 142 adjusts the bit line bias higher (e.g., 0.6V) for next pulse and for cells targeting L2-L7, the media operations manager 142 keeps the bit line at 0V for continued full programming.

The media operations manager 142 can apply a second pulse with Vpgm of 14.3V. The media operations manager 142 for L1 cells that showed fast VgVt can apply increased bit line bias to slow programming. For L1 cells, the media operations manager 142 can still program by keeping the original bit line bias. The media operations manager 142 can verify L1 cells and measure VgVt for L2 cells. Based on the L2 VgVt measurements, the media operations manager 142 can prepare bit line bias adjustments for next pulse. The media operations manager 142 can apply a third pulse with Vpgm of 15.6V. The media operations manager 142 can determine that L1 cells complete programming. For L2 cells, the media operations manager 142 can apply customized bit line biases based on previous VgVt, where fast L2 cells get higher bit line voltage to slow programming and slow L2 cells maintain lower bit line voltage. The media operations manager 142 can verify L2 and measure L3 VgVt. This pattern continues through all levels (L1-L7), with VPGM increasing from 13.0V to 22.1V.

Each pulse is designed to complete programming of one voltage level, moving sequentially through the levels rather than programming all levels simultaneously. This level-by-level approach with analog bit line biasing provides more precise control over the final threshold voltage distributions. The incrementally increasing pulse heights shown in FIG. 3 enable consistent programming across all cells while maintaining tight threshold voltage distributions. The verify operations ensure accurate placement of threshold voltages at each target level.

The overall programming scheme represents an advanced programming approach that balances programming speed with accuracy by utilizing analog bit line biasing and level-by-level programming. This makes it particularly suitable for applications requiring fast programming while maintaining precise threshold voltage control.

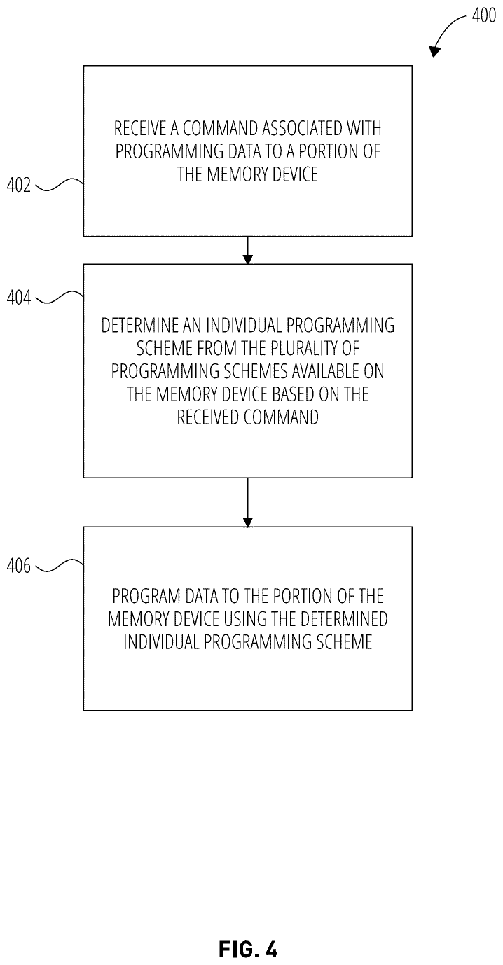

FIG. 4 illustrates a diagram 400 of operations performed using the media operations manager 142, in accordance with some examples. The method or process of diagram 400 can be performed by processing logic that can include hardware (e.g., a processing device, circuitry, dedicated logic, programmable logic, microcode, hardware of a device, an integrated circuit, etc.), software (e.g., instructions run or executed on a processing device), or a combination thereof. In some examples, the method or process of diagram 400 is performed by the memory sub-system controller 115, local media controllers 135, and/or subcomponents of the memory sub-system controller 115 and/or local media controllers 135 of FIG. 1. In these examples, the method or process of diagram 400 can be performed, at least in part, by the media operations manager 142. Although the processes are shown in a particular sequence or order, unless otherwise specified, the order of the processes can be modified. Thus, the illustrated examples should be understood only as examples; the illustrated processes can be performed in a different order, and some processes can be performed in parallel. Additionally, one or more processes can be omitted in various examples. Thus, not all processes are required in every example, other process flows are possible.

Referring now to FIG. 4, the method begins at operation 402 with the media operations manager 142 receiving a command associated with programming data to a portion of the memory device. The command includes a prefix command that indicates which programming scheme to use from multiple programming schemes available on the memory device. At operation 404, the media operations manager 142 determines an individual programming scheme from the plurality of programming schemes based on the received command. The programming scheme can be selected based on performance requirements, such as by selecting ISPP for lower performance needs or advanced schemes, like ALP or aSSPC, for more aggressive performance targets.

At operation 406, the media operations manager 142 programs data to the portion of the memory device using the determined individual programming scheme. The programming schemes can be implemented across different memory types (MLC, TLC, QLC, SLC), programming orders (D2S or S2D), and block types (normal, partial good, or block by deck). This flexible approach allows the memory device to optimize programming based on specific product requirements while maintaining reliability through backup schemes.

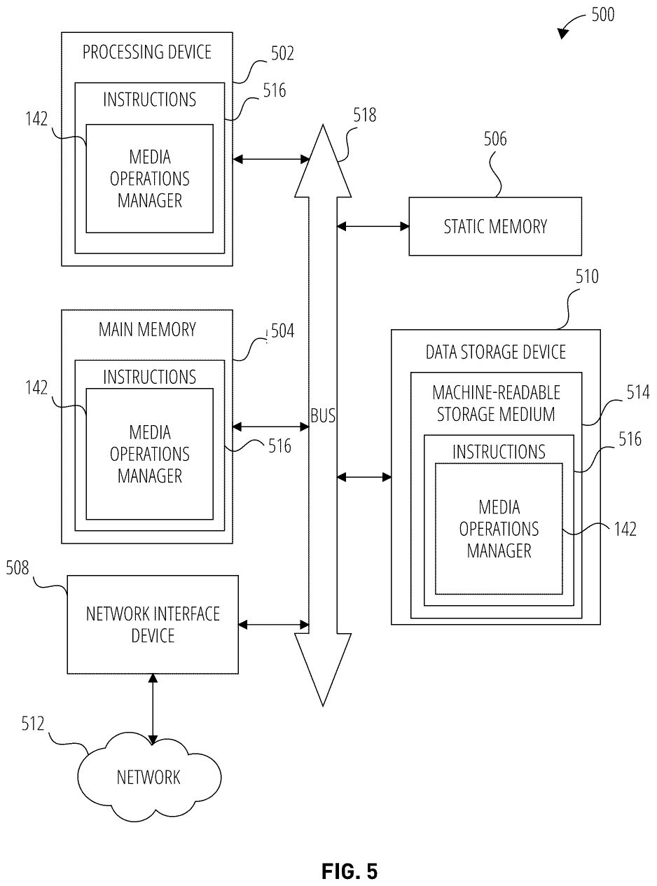

FIG. 5 illustrates an example machine in the form of a computer system 500 within which a set of instructions can be executed for causing the machine to perform any one or more of the methodologies discussed herein. In some examples, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., ROM, flash memory, DRAM such as SDRAM or Rambus DRAM (RDRAM), etc.), a static memory 506 (e.g., flash memory, static random access memory (SRAM), etc.), and a data storage device 510, which communicate with each other via a bus 518.

The processing device 502 represents one or more general-purpose processing devices such as a microprocessor, a central processing unit, or the like. More particularly, the processing device 502 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 502 can also be one or more special-purpose processing devices such as an application-specific integrated circuit (ASIC), a field programmable gate array (FPGA), a digital signal processor (DSP), a network processor, or the like. The processing device 502 is configured to execute instructions 516 for performing the operations and steps discussed herein. The computer system 500 can further include a network interface device 508 to communicate over a network 512.

The data storage device 510 can include a machine-readable storage medium 514 (also known as a computer-readable medium) on which is stored one or more sets of instructions 516 or software embodying any one or more of the methodologies or functions described herein. The instructions 516 can also reside, completely or at least partially, within the main memory 504 and/or within the processing device 502 during execution thereof by the computer system 500, the main memory 504 and the processing device 502 also constituting machine-readable storage media. The machine-readable storage medium 514, data storage device 510, and/or main memory 504 can correspond to the memory sub-system 110 of FIG. 1.

In one example, the instructions 516 include instructions to implement functionality corresponding to providing various memory operations as described herein (e.g., the media operations manager 142 of FIG. 1). While the machine-readable storage medium 514 is shown in an example to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Described implementations of the subject matter can include one or more features, alone or in combination as illustrated below by way of examples.

Example 1. A system comprising: a memory device comprising a plurality of programming schemes each associated with a different programming speed; and a processing device, operatively coupled to the memory device, programmed to perform operations comprising: receiving a command associated with programming data to a portion of the memory device; determining an individual programming scheme from the plurality of programming schemes available on the memory device based on the received command; and programming data to the portion of the memory device using the determined individual programming scheme.

Example 2. The system of Example 1, wherein the programming scheme is specified in the command based on a specification indicating a minimum programming speed for the memory device.

Example 3. The system of any one of Examples 1-2, wherein the plurality of programming schemes comprises an incremental step program pulse (ISPP) scheme and at least one advanced programming scheme.

Example 4. The system of Example 3, wherein the at least one advanced programming scheme comprises an all-level programming (ALP) scheme that simultaneously programs multiple levels by applying different bit line biases.

Example 5. The system of Example 4, wherein the ALP scheme applies programming pulses to program memory cells to their target levels in a single programming phase by toggling bit line biases at different Vpass thresholds and ramping a staircase Vpass for unselected word lines.

Example 6. The system of any one of Examples 3-5, wherein the at least one advanced programming scheme comprises an analog selective slow program convergence (aSSPC) scheme that provides finer granularity of bit line bias control during programming.

Example 7. The system of Example 6, wherein the aSSPC is programmed to perform operations comprising: checking a program speed (VgVt) of memory cells from a previous program verify operation; adjusting bit line bias voltages during a current program pulse based on the checked program speed; and programming one level in one program pulse by applying the adjusted bit line bias voltages to complete programming of each level sequentially.

Example 8. The system of any one of Examples 3-7, wherein the ISPP scheme applies a smaller voltage step size to an individual WL than the at least one advanced programming scheme to achieve more accurate voltage threshold placement.

Example 9. The system of any one of Examples 1-8, wherein the command comprises a prefix command that indicates which programming scheme to use.

Example 10. The system of any one of Examples 1-9, wherein the portion of the memory device comprises a single-level cell (SLC) memory or dual SLC with pillar float.

Example 11. The system of any one of Examples 1-10, wherein the programming operation comprises programming in a drain to source (D2S) direction or a source to drain (S2D) direction.

Example 12. The system of any one of Examples 1-11, wherein the portion of the memory device comprises a normal memory block, a partial good block, or a block by deck.

Example 13. The system of any one of Examples 1-12, the memory device comprising at least one of a multi-level cell (MLC) memory device, a tri-level cell (TLC) memory device, or quad-level cell (QLC) memory device.

Example 14. The system of any one of Examples 1-13, wherein the memory device comprises a three-dimensional (3D) NAND device.

Example 15. The system of any one of Examples 1-14, wherein the memory device comprises a non-volatile memory device comprising at least one of resistive random-access memory (ReRAM), and phase-change memory (PCM).

Example 16. The system of any one of Examples 1-15, wherein the plurality of programming schemes comprises at least three different programming schemes implemented in the same memory device.

Example 17. The system of any one of Examples 1-16, wherein the portion of the memory device comprises a plurality of sub-blocks, the operations comprising: determining a first programming scheme for a first sub-block based on a first performance specification; determining a second programming scheme for a second sub-block based on a second performance specification that is different from the first performance specification; and programming data to the first sub-block using the first programming scheme while programming data to the second sub-block using the second programming scheme.

Example 18. The system of any one of Examples 1-17, the operations comprising: monitoring programming performance metrics during operation of the memory device; determining that a programming performance need has changed based on the monitored performance metrics; selecting a different programming scheme from the plurality of programming schemes in response to determining the programming performance need has changed, wherein: when the performance need becomes more aggressive, an advanced programming scheme that provides faster programming speed is selected, and when the performance need becomes less stringent, an incremental step program pulse (ISPP) scheme is selected; and programming subsequent data to the portion of the memory device using the selected different programming scheme.

Example 19. At least one non-transitory machine-readable storage medium comprising instructions that, when executed by a processing device, cause the processing device to perform operations comprising: receiving a command associated with programming data to a portion of a memory device; determining an individual programming scheme from a plurality of programming schemes available on the memory device based on the received command; and programming data to the portion of the memory device using the determined individual programming scheme.

Example 20. A method comprising: receiving a command associated with programming data to a portion of a memory device; determining an individual programming scheme from a plurality of programming schemes available on the memory device based on the received command; and programming data to the portion of the memory device using the determined individual programming scheme.

The term “coupled with” generally refers to a connection between components, which can be an indirect communicative connection or direct communicative connection (e.g., without intervening components), whether wired or wireless, including connections such as electrical, optical, magnetic, and the like.

“System data” hereinafter refers to data that is created and/or maintained by the memory sub-system for performing operations in response to host requests and for media management.

“User data” hereinafter generally refers to host data and garbage collection data.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, ROMs, RAMs, EPROMs, EEPROMs, magnetic or optical cards, or any type of media suitable for storing electronic instructions, each coupled to a computer system bus.

The algorithms and displays presented herein are not inherently related to any particular computer or other apparatus. Various general-purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium (such as a non-transitory machine-readable medium) having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a ROM, RAM, magnetic disk storage media, optical storage media, flash memory components, and so forth. A machine-readable storage medium can be non-transitory (in other words, not having any transitory signals) in that it does not embody a propagating signal. However, labeling a machine-readable storage medium “non-transitory” should not be construed to mean that the machine-readable storage medium is incapable of movement; the machine-readable storage medium should be considered as being transportable from one physical location to another.

In the foregoing specification, examples of the disclosure have been described with reference to specific examples thereof. It will be evident that various modifications can be made thereto without departing from the broader scope of examples of the disclosure as set forth in the following claims. The specification and drawings are, accordingly, to be regarded in an illustrative sense rather than a restrictive sense.

1. A system comprising:
a memory device comprising a plurality of programming schemes each associated with a different programming speed; and
a processing device, operatively coupled to the memory device, programmed to perform operations comprising:
receiving a command associated with programming data to a portion of the memory device;
determining an individual programming scheme from the plurality of programming schemes available on the memory device based on the received command; and
programming data to the portion of the memory device using the determined individual programming scheme.

2. The system of claim 1, wherein the programming scheme is specified in the command based on a specification indicating a minimum programming speed for the memory device.

3. The system of claim 1, wherein the plurality of programming schemes comprises an incremental step program pulse (ISPP) scheme and at least one advanced programming scheme.

4. The system of claim 3, wherein the at least one advanced programming scheme comprises an all-level programming (ALP) scheme that simultaneously programs multiple levels by applying different bit line biases.

5. The system of claim 4, wherein the ALP scheme applies programming pulses to program memory cells to their target levels in a single programming phase by toggling bit line biases at different Vpass thresholds and ramping a staircase Vpass for unselected word lines.

6. The system of claim 3, wherein the at least one advanced programming scheme comprises an analog selective slow program convergence (aSSPC) scheme that provides finer granularity of bit line bias control during programming.

7. The system of claim 6, wherein the aSSPC is programmed to perform operations comprising:
checking a program speed (VgVt) of memory cells from a previous program verify operation;
adjusting bit line bias voltages during a current program pulse based on the checked program speed; and
programming one level in one program pulse by applying the adjusted bit line bias voltages to complete programming of each level sequentially.

8. The system of claim 3, wherein the ISPP scheme applies a smaller voltage step size to an individual WL than the at least one advanced programming scheme to achieve more accurate voltage threshold placement.

9. The system of claim 1, wherein the command comprises a prefix command that indicates which programming scheme to use.

10. The system of claim 1, wherein the portion of the memory device comprises a single-level cell (SLC) memory or dual SLC with pillar float.

11. The system of claim 1, wherein the programming operation comprises programming in a drain to source (D2S) direction or a source to drain (S2D) direction.

12. The system of claim 1, wherein the portion of the memory device comprises a normal memory block, a partial good block, or a block by deck.

13. The system of claim 1, the memory device comprising at least one of a multi-level cell (MLC) memory device, a tri-level cell (TLC) memory device, or quad-level cell (QLC) memory device.

14. The system of claim 1, wherein the memory device comprises a three-dimensional (3D) NAND device.

15. The system of claim 1, wherein the memory device comprises a non-volatile memory device comprising at least one of resistive random-access memory (ReRAM) and phase-change memory (PCM).

16. The system of claim 1, wherein the plurality of programming schemes comprises at least three different programming schemes implemented in the same memory device.

17. The system of claim 1, wherein the portion of the memory device comprises a plurality of sub-blocks, the operations comprising:
determining a first programming scheme for a first sub-block based on a first performance specification;
determining a second programming scheme for a second sub-block based on a second performance specification that is different from the first performance specification; and
programming data to the first sub-block using the first programming scheme while programming data to the second sub-block using the second programming scheme.

18. The system of claim 1, the operations comprising:
monitoring programming performance metrics during operation of the memory device;
determining that a programming performance need has changed based on the monitored performance metrics;
selecting a different programming scheme from the plurality of programming schemes in response to determining the programming performance need has changed, wherein:
when the performance need becomes more aggressive, an advanced programming scheme that provides faster programming speed is selected, and
when the performance need becomes less stringent, an incremental step program pulse (ISPP) scheme is selected; and
programming subsequent data to the portion of the memory device using the selected different programming scheme.

19. At least one non-transitory machine-readable storage medium comprising instructions that, when executed by a processing device, cause the processing device to perform operations comprising:
receiving a command associated with programming data to a portion of a memory device;
determining an individual programming scheme from a plurality of programming schemes available on the memory device based on the received command; and
programming data to the portion of the memory device using the determined individual programming scheme.

20. A method comprising:
receiving a command associated with programming data to a portion of a memory device;
determining an individual programming scheme from a plurality of programming schemes available on the memory device based on the received command; and
programming data to the portion of the memory device using the determined individual programming scheme.
